(19) United States
(12) Patent Application Publication
(10) Pub. No.: US 2007/0222076 A1
(43) Pub. Date: Sep. 27, 2007

(54) Single or dual damascene structure reducing or eliminating the formation of micro-trenches arising from lithographic misalignment

(76) Inventors: Masanaga Fukasawa, Fishkill, NY (US); Takashi Nogami, Chappaqua, NY (US)

Correspondence Address: MAYER & WILLIAMS PC, 251 NORTH AVE. WEST, 2ND FLOOR, WESTFIELD, NJ, 07090, US

(21) Appl. No.: 11/386,022

(22) Filed: Mar. 21, 2006

(51) Int. Cl. H01L 23/52

(52) U.S. Cl. 257/751

(57) ABSTRACT

A semiconductor device is provided that includes a substrate, a lower dielectric layer located on a substrate, and at least one lower conductive interconnect located in the lower dielectric layer. A cap layer is located over the lower conductive interconnect and at least a first dielectric layer is located on the cap layer. At least a first trench/via is formed through the first dielectric layer and the cap layer and is at least in part located over a portion of the lower conductive interconnect. The portion of the lower conductive interconnect defines a chamfered shoulder. A barrier layer lines the first trench/via. A conductive material fills the first trench/via and also fills a region of the lower dielectric layer adjacent the chamfered shoulder of the lower conductive interconnect.

### FIELD OF THE INVENTION

The present invention relates generally to damascene interconnections for integrated circuits, and more specifically to a damascene interconnection that eliminates micro-structures that can form as a result of lithographic misalignments.

### BACKGROUND OF THE INVENTION

The manufacture of integrated circuits in a semiconductor device involves the formation of a sequence of layers that contain metal wiring. Metal interconnects and vias which form horizontal and vertical connections in the device are separated by insulating layers or inter-level dielectric layers (ILDs) to provide electrical insulation between metal wires and prevent crosstalk between the metal wiring that can degrade device performance.

A popular method of forming an interconnect structure is a dual damascene process in which vias and trenches are filled with metal in the same step to create multi-level, high density metal interconnections needed for advanced high performance integrated circuits. The most frequently used approach is a via first process in which a via is formed in a dielectric layer and then a trench is formed above the via. Recent achievements in dual damascene processing include lowering the resistivity of the metal interconnect by switching from aluminum to copper, decreasing the size of the vias and trenches with improved lithographic materials and processes to improve speed and performance, and reducing the dielectric constant (k) of insulators or ILDs by using so-called low k materials to avoid capacitance coupling between the metal interconnects. The expression “low-k” material has evolved to characterize materials with a dielectric constant less than about 3.9. One class of low-k material that have been explored are organic low-k materials, typically having a dielectric constant of about 2.0 to about 3.8, which may offer promise for use as an ILD. Another class of low-k materials that have been also explored are SiCOH materials, which typically have a dielectric constant of about 2.0 to about 3.5.

A cap layer is generally required to serve as a hardmask when a second interconnection (i.e., a trench or via) is etched in an ILD over a first interconnection (i.e., a trench or via). Without the additional cap layer, so-called micro-trenches may be formed in the ILD as a result of lithographic misalignment. Unfortunately, despite the use of a cap layer, which is typically silicon nitride or silicon carbide, micro-trenches may still form as a result of low etching selectivity between the cap layer and the ILD.

Accordingly, it would be desirable to provide a damascene structure that eliminates micro-structures that can form as a result of lithographic misalignments.

### SUMMARY OF THE INVENTION

In accordance with the present invention, a semiconductor device is provided that includes a substrate, a lower dielectric layer located on a substrate, and at least one lower conductive interconnect located in the lower dielectric layer. A cap layer is located over the lower conductive interconnect and at least a first dielectric layer is located on the cap layer. At least a first trench/via is formed through the first dielectric layer and the cap layer and is at least in part located over a portion of the lower conductive interconnect. The portion of the lower conductive interconnect defines a chamfered shoulder. A barrier layer lines the first trench/via. A conductive material fills the first trench/via and also fills a region of the lower dielectric layer adjacent the chamfered shoulder of the lower conductive interconnect.

In accordance with one aspect of the invention, the lower and first dielectric layers are formed from a low-k dielectric material.

In accordance with another aspect of the invention, the conductive material is copper.

In accordance with another aspect of the invention, the trench/via comprises a trench and a via.

In accordance with another aspect of the invention, the trench/via comprises either a trench or a via.

In accordance with another aspect of the invention, a protective liner is located between the barrier layer and the conductive material filling the first trench/via.

In accordance with another aspect of the invention, the first dielectric layer includes SiOCH.

In accordance with another aspect of the invention, the first dielectric layer is selected from the group consisting of Black Diamond™ and Coral™.

In accordance with another aspect of the invention, a method is provided of forming a semiconductor device. The method begins by forming a lower dielectric layer on a substrate. The lower dielectric layer includes at least one lower conductive interconnect therein. A cap layer is formed over the lower conductive interconnect and at least a first dielectric layer is formed on the cap layer. At least a first trench/via is etched in the first dielectric layer and is located at least in part over the conductive interconnect. The cap layer is etched through the first trench/via to expose a portion of the conductive interconnect, whereby a micro-trench is formed in the lower dielectric layer adjacent the conductive interconnect. The exposed portion of the conductive interconnect is chamfered. A barrier layer lines the first trench/via; and a conductive material is deposited to fill the first trench/via.

In accordance with another aspect of the invention, the exposed portion of the conductive interconnect is chamfered by wet etching.

### BRIEF DESCRIPTION OF THE DRAWINGS

FIGS. 1-10 show cross-sectional views illustrating the formation of a dual damascene structure.

FIG. 11 shows the dual damascene structure of FIG. 10 with a micro-trench located therein.

FIGS. 12-13 show a dual damascene structure with a lower conductive interconnect that is chamfered to eliminate the micro-trench shown in FIG. 11.

FIGS. 14 show a protective liner that may be employed to prevent the trench and via from being chamfered.

FIG. 15 shows the chamfering that may arise to the trench and via if a protective liner is not employed.

### DETAILED DESCRIPTION

The methods and structures described herein do not form a complete process for manufacturing semiconductor device structures. The remainder of the process is known to those of ordinary skill in the art and, therefore, only the process steps and structures necessary to understand the present invention are described herein.

The present invention can be applied to microelectronic devices, such as highly integrated circuit semiconductor devices, processors, micro electromechanical (MEM) devices, optoelectronic devices, and display devices. In particular, the present invention is highly useful for devices requiring high-speed characteristics, such as central processing units (CPUs), digital signal processors (DSPs), combinations of a CPU and a DSP, application specific integrated circuits (ASICs), logic devices, and SRAMs.

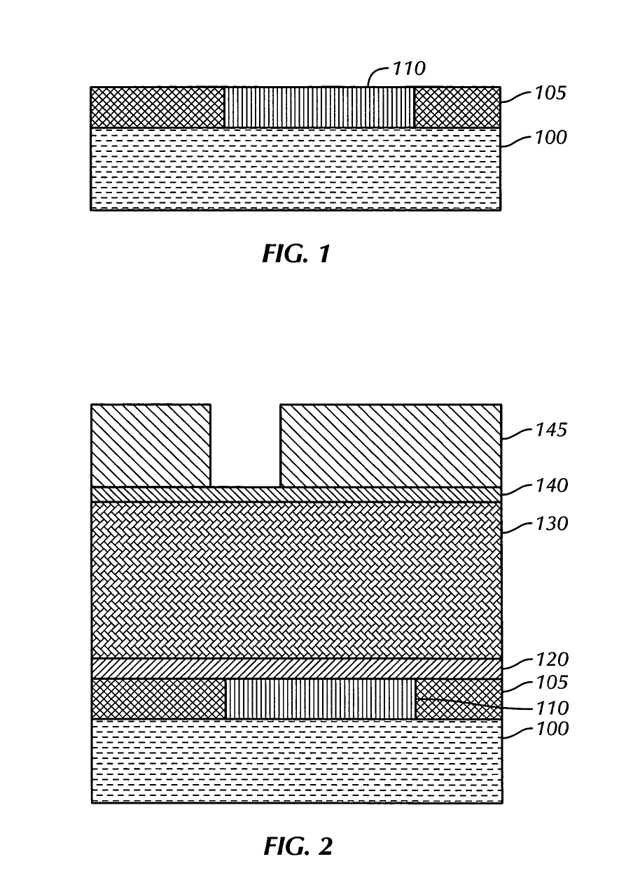

In the present invention voids that can arise as a result of lithographic misalignments are reduced or eliminated by chamfering or beveling a portion of the a lower conductive interconnect that is adjacent to the micro-trench. A method of fabricating dual damascene interconnections according to an embodiment of the present invention will now be described with reference to FIG. 1 through 15.

As shown in FIG. 1, a substrate 100 is prepared. A lower ILD 105 including a lower interconnection 110 is formed on the substrate 100. The substrate 100 may be, for example, a silicon substrate, a silicon on insulator (SOI) substrate, a gallium arsenic substrate, a silicon germanium substrate, a ceramic substrate, a quartz substrate, or a glass substrate for display. Various active devices and passive devices may be formed on the substrate 100. The lower interconnection 110 may be formed of various interconnection materials, such as copper, copper alloy, aluminum, and aluminum alloy. The lower interconnection 110 is preferably formed of copper because of its low resistivity. Also, the surface of the lower interconnection 110 is preferably planarized.

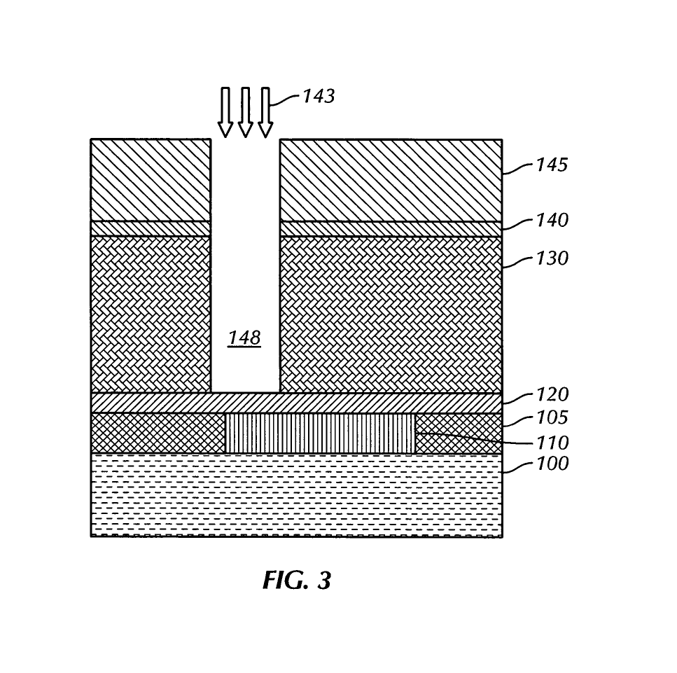

Referring to FIG. 2, a cap layer 120, a low-k ILD 130, and an optional hard mask 140 are sequentially stacked on the surface of the substrate 100 where the lower interconnection 110 is formed, and a photoresist pattern 145 is formed on the hard mask 140 to define a via.

The cap layer 120 is formed to prevent electrical properties of the lower interconnection 110 from being damaged during a subsequent etch process for forming a trench and via. Accordingly, the cap layer 120 is formed of a material having a high etch selectivity with respect to the ILD 130 formed thereon. Preferably, the cap layer 120 is formed of SiC, SiN, or SiCN, having a dielectric constant of about 3 to 5. The cap layer 120 is as thin as possible in consideration of the effective dielectric constant of the entire ILD, but thick enough to properly function as an etch stop layer and a diffusion barrier against copper diffusion.

The ILD 130 is formed of a hybrid low-k dielectric material such as SIOCH, which has advantages of organic and inorganic materials. That is, the ILD 130 is formed of a hybrid low-k dielectric material having low-k characteristics, which can be formed using a conventional apparatus and process, and which is thermally stable. The ILD 130 has a dielectric constant of e.g., 3.5 or less, to prevent an RC delay between the lower interconnection 110 and dual damascene interconnections and minimize cross talk and capacitance. For example, the ILD 130 may be formed of low-k organosilicon material such as Black Diamond™, CORAL™, or a similar material. The ILD 130 can be formed using chemical vapor deposition (CVD), and more specifically, plasma-enhanced CVD (PECVD). The ILD 130 may be also formed from low k materials such as spin-on organics and organo silicates. The ILD 130 is formed to a thickness of about 3,000 angstroms to 20,000 angstroms or other appropriate thicknesses determined by those skilled in the art.

If employed, the hard mask 140 prevents the ILD 130 from being damaged when dual damascene interconnections are planarized using chemical mechanical polishing (CMP). Thus, the hard mask 140 may be formed of Si0₂, SiOF, SiON, SiC, SiN, or SiCN. The hard mask 140 may also function as an anti-reflection layer (ARL) in a subsequent photolithographic process for forming a via and trench. In this case the hard mask 140 is more preferably formed of Si0₂, SiON, SiC, or SiCN.

The photoresist pattern 145 is formed by forming a layer of a photoresist and then performing exposure and developing processes using a photo mask defining a via. Referring to FIG. 3, the ILD 130 is anisotropically etched (143) using the photoresist pattern 145 as an etch mask to form a via 148. The ILD 130 can be etched, for example, using a reactive ion beam etch (RIB) process, which uses a mixture of a main etch gas (e.g., CₓF_{y} and CₓH_{y}F_{z}), an inert gas (e.g. Ar gas), and possibly at least one of O₂, N₂, and COₓ. Here, the RIE conditions are adjusted such that only the ILD 130 is selectively etched and the cap layer 120 is not etched.

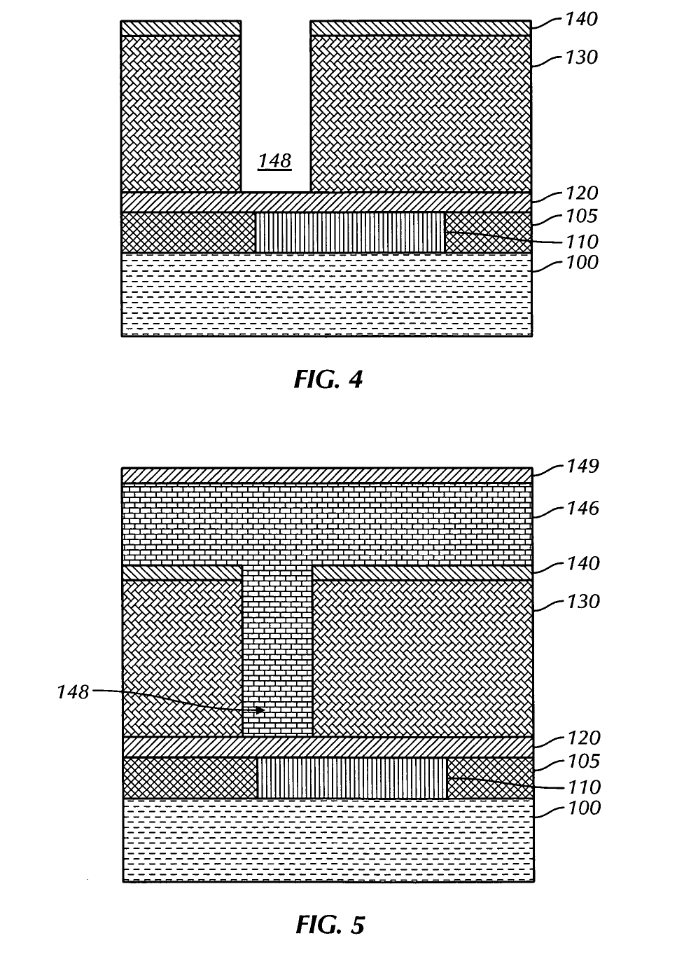

Referring to FIG. 4, the via photoresist pattern 145 is removed using a plasma etch, for example. In FIG. 5, the via formed in the previous step is filled with an organic polymer back filling material 146 that is spin-coated and baked. A material layer 149 such as Si0₂, SiON, SiC, or SiCN is deposited over the back filling material using CVD or spin-coating. Since the back filling material 146 and resist material 147 that is subsequently deposited over it are organic, it is difficult to achieve highly selective etching of them and thus material layer 149 is often provided for this purpose.

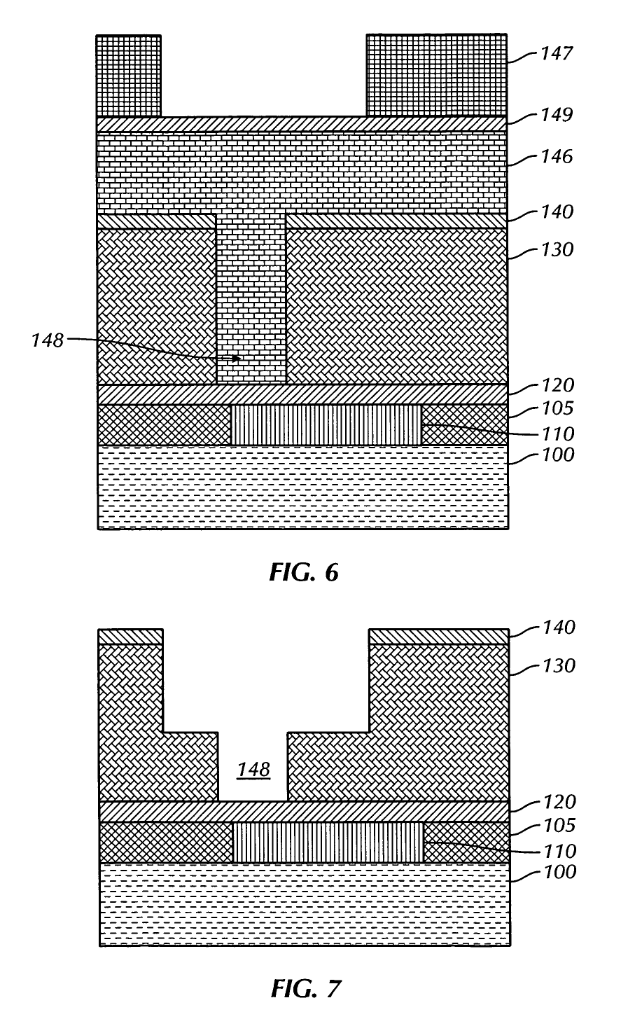

In FIG. 6 a photoresist trench pattern 147 is defined in a lithography process over the material layer 149. The trench pattern is transferred to the ILD layer by dry etching of the material layer 149, back filling material 146, the hard mask 140, and the ILD 130. The etching is stopped halfway during the etching of the ILD 130 as shown in FIG. 7. After the plasma dry etching, the photoresist 147 and the remained filling back material 146 are removed by oxygen plasma, for example (FIG. 7). Then, the cap layer 120 at the bottom of the via is removed by dry etching to expose the copper surface of the lower interconnection 110. This dry etching to remove the etching stop layer is selectively performed where the etching stop layer 110 such as SiC and SiN is etched while the ILD layer in the lower interconnection 105 is not etched. (FIG. 8)

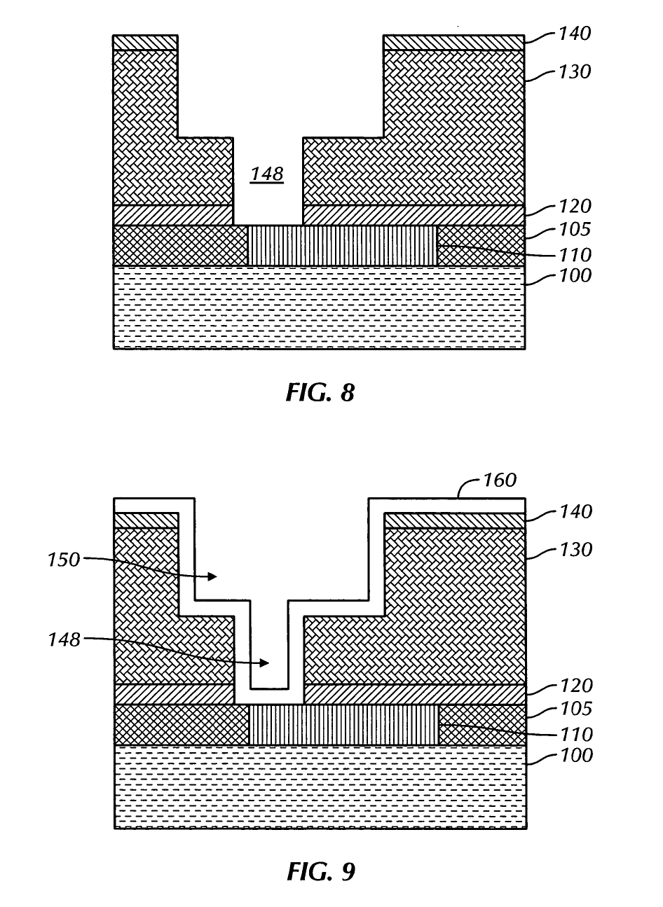

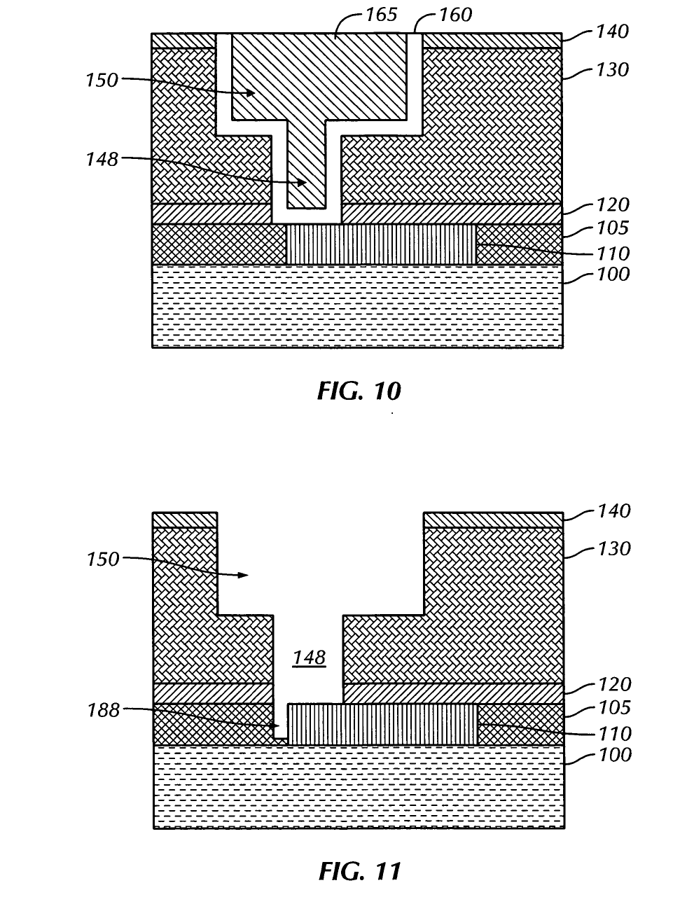

In FIG. 9 a barrier layer 160 lines the via 148 and the trench 150 to prevent the subsequently formed copper conductive layer from diffusing into ILD 130. The barrier layer 160 is generally formed from a conventional material such as tantalum, tantalum nitride, titanium, titanium silicide or zirconium. After formation of the barrier layer 160 the copper conductive layer is formed on the liner by an electroplating process. The bulk copper layer 165 is formed by electroplating and then planarized in FIG. 10.

The above-described process is an idealization that assumes no errors arise during processing. However, errors such as lithographic misalignments can arise in the formation of the various features such as the trench and via. For instance, instead of forming via 148 in the ideal manner shown in FIG. 8, misalignments may give rise to the micro-trench 188 shown in FIG. 11 when cap layer 120 is etched because of the generally low etching selectivity between cap layer 120 and lower ILD 105. That is, a micro-trench 188 may be formed in lower ILD 105 adjacent the lower interconnection 110 because of the cap layer 12—etching process. In other words, the etching step used to etch cap layer 120 may also expose the ILD 105 to the etching gases (e.g., CH₂F₂, NF₃, SF₆, CF₄), thereby creating the micro-trench 188. Even without lithographic misalignments, ILD 105 may be over-etched in FIG. 8. Such over-etching is performed to ensure that a reliable contact is made to the lower interconnect 110.

Because the degree of misalignment is likely to be small, the micro-trench 188 will generally be relatively narrow in the lateral direction. That is, the micro-trench will have a high aspect ratio. Because of its high aspect ratio, the micro-trench 188 can be difficult to fill or otherwise eliminate. The void that results after the via 148 is filled can reduce the reliability of the interconnect.

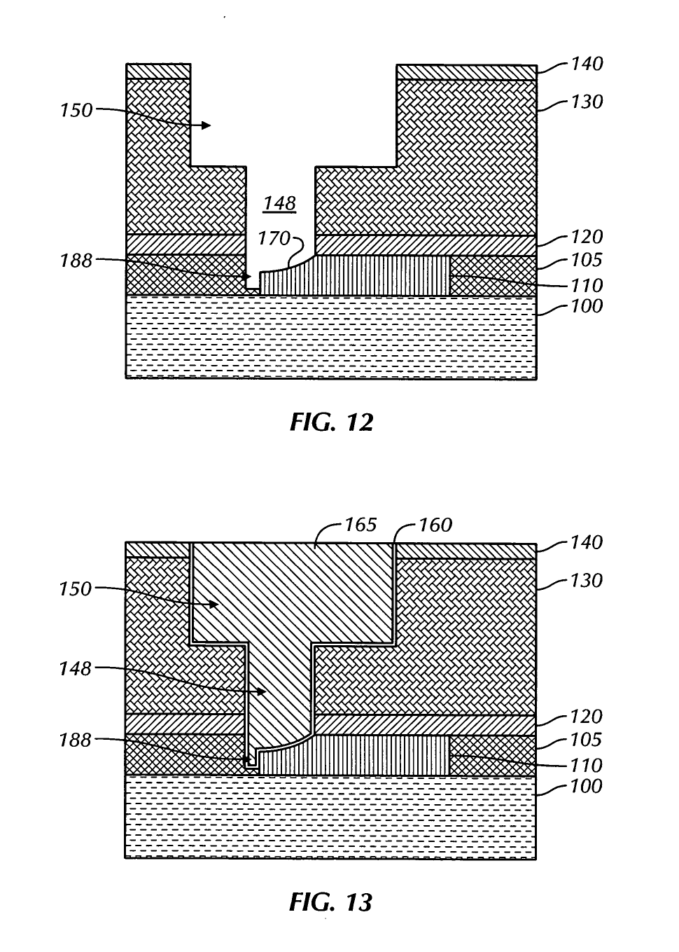

In accordance with the present invention, the void that arises because of the formation of micro-trench 188 can be eliminated by chamfering the lower interconnection 110 to define a shoulder 170 prior to filling the via 148 (see FIG. 12). In this way the aspect ratio of micro-trench 188 is effectively reduced, thereby allowing it to be filled more readily.

The lower interconnection 110, generally formed from copper, may be chamfered by any appropriate etching technique such as wet etching, plasma etching, or sputtering with a noble gas. If wet etching is employed, amine solvent may be used since it can form a copper complex that can be liquated out. If plasma etching is employed, Cl₂ gas can be used to etch the copper at high temperatures over about 200 degrees C. In sputtering, Ar is commonly employed and may also be used in this case to etch the lower interconnection 110 as well.

After the lower interconnection 110 is chamfered, the barrier layer 160 and conductive material can be deposited as discussed above, resulting in the dual damascene interconnection shown in FIG. 13. Since the aspect ratio of the micro-trench 188 has been reduced, the void that would otherwise arise is substantially reduced in dimension or even eliminated.

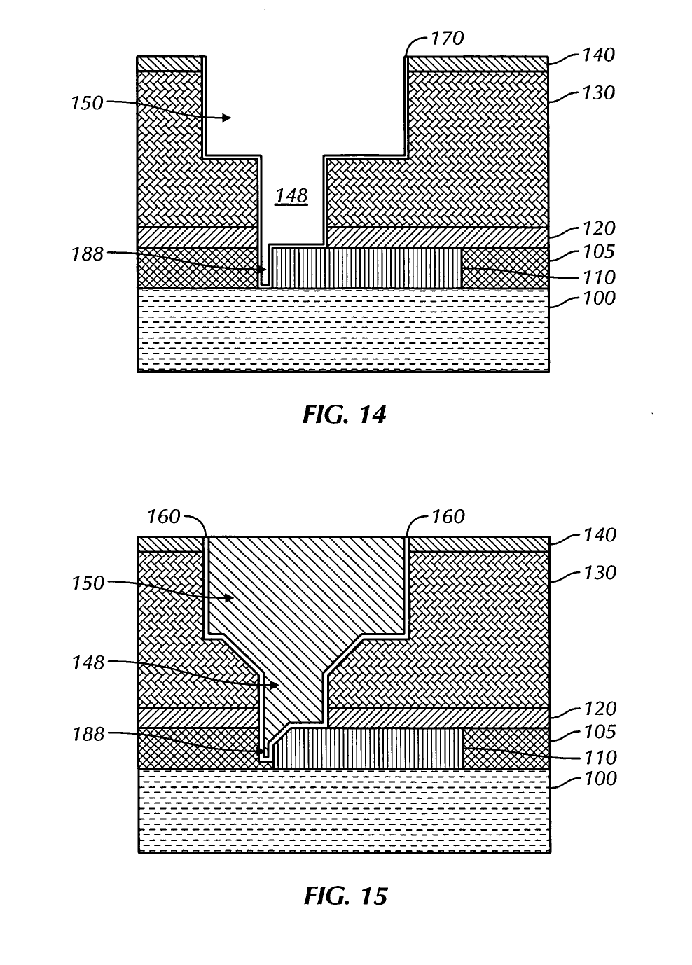

In one alternative embodiment of the invention shown in FIGS. 14-15 a protective liner 170 is deposited over the via 148 and trench 150 prior to chamfering the lower interconnection 110. The protective liner 170 prevents the trench and via from being chamfered during the etching or sputtering process. If the protective liner 170 were not employed, the trench and via may be chamfered in the manner shown in FIG. 15. The protective liner 170 may be formed from a dense (i.e., non-porous) low k material. Other materials that may be employed for protective liner 170 include SiO2, SiN, SiCOH, SiCN, SiC, SiON, organic films, and metals such as Ta, TaN, Ti, TiN, for example.

Although various embodiments are specifically illustrated and described herein, it will be appreciated that modifications and variations of the present invention are covered by the above teachings and are within the purview of the appended claims without departing from the spirit and intended scope of the invention.

1. A semiconductor device, comprising:
a substrate;
a lower dielectric layer located on a substrate;
at least one lower conductive interconnect located in the lower dielectric layer;
a cap layer located over the lower conductive interconnect;
at least a first dielectric layer located on the cap layer;
at least a first trench/via formed through the first dielectric layer and the cap layer and being at least in part located over a portion of the lower conductive interconnect, wherein said portion of the lower conductive interconnect defines a chamfered shoulder;
a barrier layer lining the first trench/via; and
a conductive material filling the first trench/via including a region of the lower dielectric layer adjacent the chamfered shoulder of the lower conductive interconnect.

2. The semiconductor device of claim 1 wherein said lower and first dielectric layers are formed from a low-k dielectric material.

3. The semiconductor device of claim 1 wherein the conductive material is copper.

4. The semiconductor device of claim 1 wherein the trench/via comprises a trench and a via.

5. The semiconductor device of claim 1 wherein the trench/via comprises either a trench or a via.

6. The semiconductor device of claim 1 further comprising a protective liner located between the barrier layer and the conductive material filling the first trench/via.

7. The semiconductor device of claim 1 wherein the first dielectric layer includes SiOCH.

8. The semiconductor device of claim 1 wherein the first dielectric layer is selected from the group consisting of Black Diamond™ and Coral™.

9. A method of forming a semiconductor device, comprising:
forming a lower dielectric layer on a substrate, said lower dielectric layer including at least one lower conductive interconnect therein;
forming a cap layer over the lower conductive interconnect;
forming at least a first dielectric layer on the cap layer;
etching at least a first trench/via in the first dielectric layer and at least in part over the conductive interconnect;
etching the cap layer through the first trench/via to expose a portion of the conductive interconnect, whereby a micro-trench is formed in the lower dielectric layer adjacent the conductive interconnect;
chamfering the exposed portion of the conductive interconnect;
forming a barrier layer lining the first trench/via; and
depositing conductive material to fill the first trench/via.

10. The method of claim 9 wherein the exposed portion of the conductive interconnect is chamfered by wet etching.

11. The method of claim 9 further comprising forming a protective film over the barrier layer.

12. The method of claim 10 further comprising forming a protective film over the barrier layer.

13. The method of claim 12 wherein the chamfering step is performed after forming the barrier layer and the protective film.

14. The method of claim 9 wherein said lower and first dielectric layers are formed from a low-k dielectric material.

15. The method of claim 9 wherein the conductive material is copper.

16. The method of claim 9 wherein the step of forming at least a first trench/via comprises forming a trench and a via.

17. The method of claim 9 wherein the step of forming at least a first trench/via comprises forming either a trench or a via.

18. The method of claim 9 further comprising forming a protective liner between the barrier layer and the conductive material filling the first trench/via.

19. The method of claim 9 wherein the first dielectric layer includes SiOCH.

20. The method of claim 9 wherein the first dielectric layer is selected from the group consisting of Black Diamond™ and Coral™.
